(19) United States
(12) Patent Application Publication
(10) Pub. No.: US 2026/0314336 A1
(43) Pub. Date: Oct. 8, 2026

(54) Improved Run-to-Run Control in Semiconductor Manufacturing

(71) Applicant: Robert Bosch GmbH, Stuttgart (DE)

(72) Inventors: Andreas Finn, Dresden (DE); Ulrich Potthoff, Dresden (DE)

(21) Appl. No.: 19/478,936

(22) PCT Filed: Apr. 18, 2024
(86) PCT No.: PCT/EP2024/060500

§ 371 Date: Oct. 27, 2025

(30) Foreign Application Priority Data
Apr. 28, 2023 (DE) 10 2023 204 001.8

(51) Int. Cl. H10P 74/00

(52) U.S. Cl. CPC H10P 74/23

(57) ABSTRACT

A method is for adjusting a process control for manufacturing a component in production. The method includes obtaining measurement results based on the component, and defining a process step with which the component is to be processed. The method further includes determining a parameterization of the process step by means of a run-to-run (“R2R”) controller for the process step, depending on the measurement results. The measurement results include either (i) virtual measurement results, or (ii) virtual measurement results and physical measurement results.

The invention relates to a method for improving a run-to-run (R2R) controller by taking into account artificial measurement data, as well as an apparatus, a computer program, and a machine-readable storage medium which are configured so as to carry out the method.

### PRIOR ART

It is known from the prior art that process control systems (e.g., R2R controller, statistical process control (SPC system)) receive measurements from processed wafers. The measurements are typically physical measurements on the wafer. Product parameters that are relevant for the process control can be determined based on physical measurements. These measurements include, e.g., so-called in-line measurements that can be measured on the product, preferably by means of physical measuring devices. The product parameters are exemplary: a thickness, depth, width of structures, specific resistivity, etc. By contrast, there are process and formula parameters describing a manufacturing step (illumination, etching, polishing, deposition, tempering, processing time, pressure, gas flow, dosing) on the wafer.

Based on the physical measurements, a formula suggestion for the next process step of the wafer or for the same process step of the next wafer is determined by means of an R2R controller in order to readjust accordingly if the measurements are not within a desired range.

The process step is controlled by means of piece goods control, meaning that the formula for the subsequent process step for a wafer or batch (batch of wafers) is influenced by the R2R controller. A formula characterizes the respective manufacturing step or process step, such as exposure, etching, depositing, or polishing, for example. However, the R2R controller does not intervene during the processing of the wafer/batch. This type of control is also referred to as R2R process control.

Run-to-run controllers for the manufacture of semiconductors are known. For example, see: Moyne, J. (2014). Run-to-run Control in Semiconductor Manufacturing, In: Baillieul, J., Samad, T. (eds) Encyclopedia of Systems and Control. Springer, London. https://doi.org/10.1007/978-1-4471-5102-9_255-1.

The R2R controller essentially serves to compensate for interference variables, e.g., longer-term drift in manufacturing, by means of corresponding formula adaptations during downstream processes in order to thereby maintain relevant in-line parameters at the desired target variable.

However, it is disadvantageous that product and process parameters that arise during production cannot be used directly for the process control, because the data path is undefined, not present, or difficult to implement, e.g., quality parameters of incoming material, run-time data, process data (FDC), etc. That is to say, product parameters and derived quantities from any data source are not usable for process control tasks.

US 2023/0091058 A1 discloses a process of formula creation and alignment with feature models.

### ADVANTAGES OF THE INVENTION

The objective of the present invention is to provide a virtual measuring device (“artificial, virtual sensor”), which additionally or alternatively provides further data to the R2R controller in addition to the physical measurement operation (MET), so that the R2R controller can more reliably and accurately control.

Differentiation from Virtual Metrology (VM): in VM, artificial measurement values are generated based on process parameters. By contrast, the present virtual sensor is intended to report any data and software-based artificial measurements—i.e., not only process parameters back to the process control, e.g., the R2R controller.

High transparency is ensured within the manufacturing execution system (MES) by disclosing the data path from the data source to the process control system.

A further advantage is the flexible combination of measurement formulas that can be created in any desired way, for example from simple heuristics up to complex data science applications such as aggregations, classifications, or estimation methods.

In summary, it can therefore be said that the invention allows for the physical measurement operation to be supplemented or replaced by a software-based method for the R2R controller.

### DISCLOSURE OF THE INVENTION

A first aspect of the invention relates to a method for adjusting a process control used to control a production machine during the manufacture of a component in production or manufacturing. The component is preferably a semiconductor component, such as a sensor or chip. It should be noted that the process control determined according to the method of the first aspect can be used in order to manufacture one or a plurality of components. For example, semiconductor components on a wafer or in a lot/batch can be processed substantially equally according to the determined process control.

The method begins with obtaining or receiving measurement results (MET, ART) characterizing the component. The measurement results are either virtual measurement results (ART) or they are virtual measurement results (ART) and physical measurement results (MET). “Physical measurement results” can be understood to mean that these measurement results have been detected with a real measuring device on the component. “Virtual measurement results” can be understood to determine that these measurement results are determined based on representative (measurement) values.

There can then occur an obtaining or receiving of an in particular specified process step with which the component is to be processed. The process step can be defined or otherwise specified based on a manufacturing formula for the component. In addition to the process step, an optimal process window for the process step can also be provided, so that the R2R controller can more reliably parameterize the process step by taking into account the process window. The process step thus describes how the measured component is to be further processed in the directly subsequent step, or which process step is to be carried out with which setting, which is given by the determined parameterization of the R2R controller. It is also conceivable that the process step is used for at least one subsequent component with regard to the measured component from a series of components to be processed.

This is followed by a determination of a parameterization of the process step by means of the R2R controller for the process step, depending on the measurement results (MET, ART). The R2R controller can be configured for a wafer-to-wafer or lot-to-lot or other control.

It is suggested that the virtual measurement result (ART) has been detected with a virtual measuring device, wherein the virtual measuring device carries out a measurement operation through software by means of at least one data query. Thus, a software-based measurement operation in the form of measurement formulas or computer-implemented measurement algorithms is carried out by the virtual measuring device. The virtual measuring device can also be referred to as a virtual sensor. The virtual measuring device can be configured so as to carry out one or more different measurement formulas and thus output one or a plurality of virtual measurement results.

Furthermore, it is proposed that the virtual measuring device can output same measuring device states, in particular E10 states, as a physical measuring device. Advantageously, it is now possible to simply integrate the virtual measuring device into established processes, e.g., as a plug-in. The rules applicable to physical measuring devices are thus valid and applicable without any fundamental changes. It should be noted that the virtual measuring device is perceived as a measuring device from the perspective of the R2R controller. In particular due to the communication between the R2R controller and the virtual measuring device, the virtual measuring device for the R2R controller is like a real measuring device. However, the virtual measuring device can be purely a computer program and can be run at the factory or on a server.

It is further proposed that, after carrying out the process step with the determined parameterization of the R2R controller, at least one downstream measurement operation occurs on the processed component, wherein the measurement results of the downstream measurement operation are provided to the R2R controller as further measurement results, wherein the measurement results of the downstream measurement operation are either virtual measurement results (ART) or they are virtual measurement results (ART) and physical measurement results (MET). Advantageously, feedback to the R2R controller is given in more detail with regard to its specification of the parameterization.

In further aspects, the invention relates to a device and to a computer program, which are each configured so as to carry out the aforementioned methods, and to a machine-readable storage medium on which said computer program is stored.

Embodiments of the invention are explained in greater detail below with reference to the accompanying drawings. The drawings show:

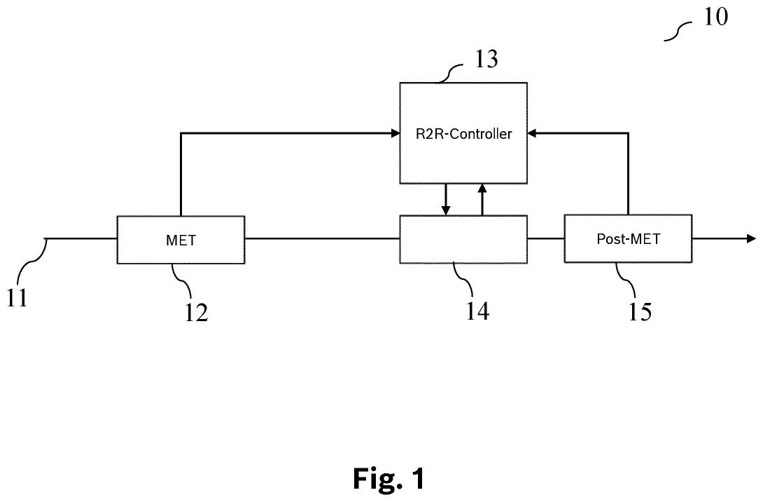

FIG. 1 schematically, a known R2R controller;

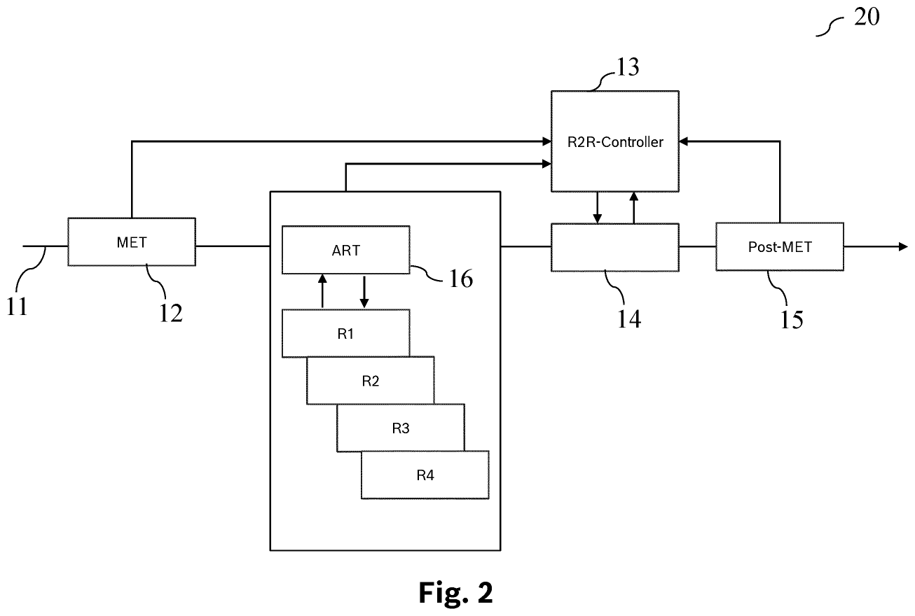

FIG. 2 schematically, one embodiment of the inventive R2R controller with the virtual sensor;

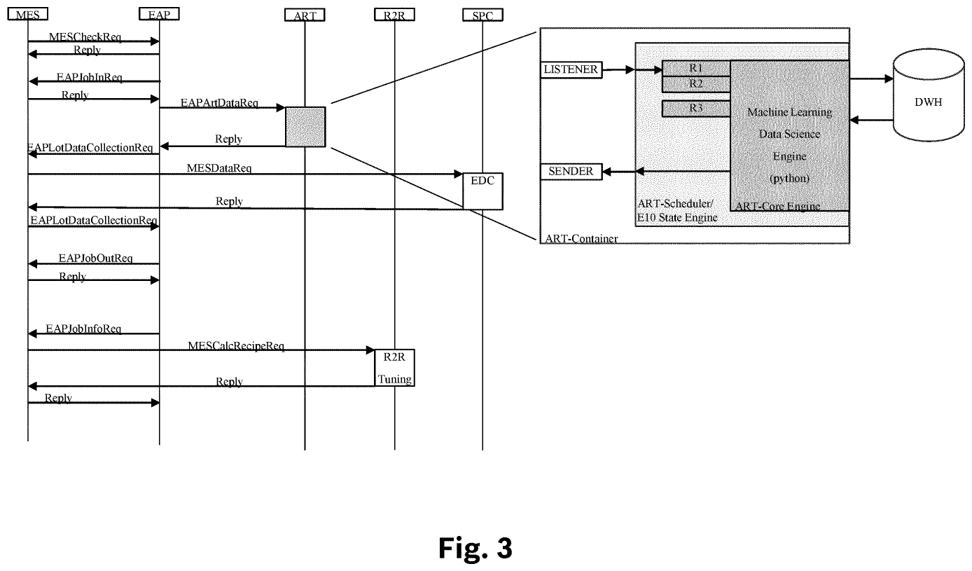

FIG. 3 schematically, a communication between an MES and the virtual sensor and the R2R controller;

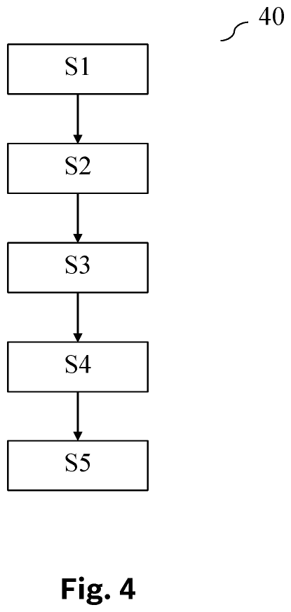

FIG. 4 schematically, a flowchart of one embodiment of the inventive method.

### DESCRIPTION OF THE EXEMPLARY EMBODIMENTS

FIG. 1 schematically shows an information flowchart 10 of an R2R controller, which is known from the prior art.

The information flowchart 10 shows a process flow 11 for manufacturing a semiconductor component. In a first step, one or a plurality of physical measurements 12 are carried out on a wafer. A measurement 12 can be a thickness, width, depth, etc. of the wafer. The measurement results MET are then forwarded and provided to the R2R controller 13.

Depending on the measurement results MET, the R2R controller 13 will adjust a process step 14 for the wafer. In other words, the R2R controller 13 outputs an adjustment for the process step 14 on the basis of the measurement results MET so that, after carrying out the process step 14, the processed wafer ideally has product parameters within a specified value range.

Optionally, after carrying out process step 14 according to the adjustment output by the R2R controller 13, one or a plurality of downstream physical measurements 15 can be carried out on the processed wafer. The measurement results obtained post-MET can be provided to the R2R controller 13 as feedback so that the latter can provide better adjustments for downstream process steps 14, on the basis of the subsequently obtained measurement results.

FIG. 2 schematically shows an information flowchart 20 of an embodiment of the R2R controller 16 according to the invention. The depicted embodiment of FIG. 2 differs from the embodiment of FIG. 1 in that the R2R controller receives measurements of a virtual sensor 16 as an additional input.

The virtual sensor 16 is handled as a virtual measuring device, which produces artificial measurement results ART and provides them to the R2R controller 13. The depicted embodiment of FIG. 2 differs, among other things, from the embodiment of FIG. 1 in that the R2R controller 13 uses these additional measurement results ART of the virtual sensor 16 in order to additionally adjust the process step 14 depending on the artificial measurement results ART.

With the virtual measuring device, it is thus possible to provide software-based measurements to the Manufacturing Execution System (MES), in particular the R2R controller, in addition to, or as an alternative to, the physical measurements (MET).

The advantage of a virtual measuring device is that it does not necessarily have to be discernible, from the perspective of the Manufacturing Execution System (MES), that no physical measurement was carried out. Thus, the virtual measuring device ART behaves like a physical measuring device with respect to the R2R controller. This can be achieved in that the virtual measuring device uses the same readiness states (e.g., according to E10 model) as physical measuring devices. Then, the virtual measuring device outwardly dictates that it is a real measuring device. Preferably, the virtual measuring device behaves the same way as a physical measuring device, by communicating the in the same manner as a true measuring device. This allows the virtual measuring device to be easily integrated into the existing Manufacturing Execution System without any basic changes, while maintaining applicable rules.

FIG. 3 schematically shows the communication between the MES and the virtual measuring device/virtual sensor and the R2R controller.

FIG. 4 schematically shows a flowchart 40 of an embodiment of the method for adjusting a process control for manufacturing a semiconductor component.

The method starts with step S1. In this step, measurement results (MET, ART) which characterize the component are provided. The measurement results are detected according to FIG. 2, i.e., the measurement results are either virtual measurement results ART or they are virtual measurement results ART and physical measurement results MET.

Then, there occurs a definition S2 of a process step 14 with which the component is to be processed. The information regarding the process step 14 can be provided via a database query.

This is followed by a determination S3 of a parameterization of the process step by means of an R2R controller for the process step 14, depending on the measurement results (MET, ART).

Optionally, after step S3, an output S4 of the determined parameterization for the process step 14 for processing the component can be carried out. Optionally, control S5 of a facility can then be carried out using the determined parameterization.

The above-described concept according to FIG. 2 and/or the method according to FIG. 4 can be used, by way of example, as follows. The different applications are indicated schematically in FIG. 2 by the measurement formulas R1-R4. A measurement formula defines how the virtual sensor carries out the measurement (mathematical algorithm) and where the data originated (data source).

In a first application example, supplier data is output by the virtual measuring device. The supplier data can be stored in a database of the Manufacturing Execution System (MES). For example, wafer thicknesses are retrieved from the database by the virtual measuring device as the measurement result ART. These are provided to the R2R controller as measurement values, which, depending thereon, provides a grinding time for the process step.

The aim of this R2R controller is to produce a specified wafer thickness and/or as uniform a wafer surface as possible.

The R2R controller can provide a proportional increase in grinding time for the processing by directly mapping the wafer thickness determined by the virtual measuring device relative to the desired wafer thickness.

Advantageously, this can be used in order to guarantee that the wafers are uniformly thick, and thus each wafer can be used under the highest quality requirements.

In a second application example, FDC process data is output by the virtual measuring device.

The virtual sensor can perform an anomaly detection of process parameters or measurement results, i.e., using data as they have been set on the production machine or as they have been carried out by the formula.

For example, the anomaly detection of process data and parameters such as temperature, pressure, or gas flow can occur, for example, in order to detect abnormal variations. These anomalies are then transmitted to the R2R controller as measurements. The R2R controller can then make corresponding formula changes, e.g., triggering corresponding countermeasures if too much fluctuation occurs.

It is also contemplated that the degree to which the respective production machine can be trusted is determined based on the strength of the variation. If the machine fluctuates sharply, it can be concluded that the machine should be less trusted. The R2R controller accordingly determines a conservative formula adjustment for the next processing if strong fluctuations have occurred. In other words, an unreliability of the manufacturing machines can be detected, and such unreliability can be considered in the process control accordingly.

In a third application example, geometry data is output by the virtual measuring device. A semiconductor coordinate database contains, among other things, the geometric design of the chip or the entire wafer, in particular geometries such as open area information. The background to this is that etching processes act differently with respect to the size of the etching surface. Thus, a time setting of the etching duration is dependent on the size of the open area (small/large of the surface). By means of the R2R controller, depending on the geometry data, in particular any intermediate stage of a design can be tapped and continuously used for controlling the etching process. This procedure can also be used accordingly for other manufacturing steps, such as implantation.

In a fourth application example, metadata is output by the virtual measuring device. Metadata can be data contained latently in a database. No stand-alone measurement device exists for this data type or datasets derived based on meta-information. For example, a period of time between a completion of a manufacturing step and the measurement operation can be included in the database by timestamps of the individual data points and provided to the process control system via the virtual measuring device.

In a fifth application example, physical measurements are (fully) replaced by virtual measurements. For example, certain product parameters can be predicted based on a measurement of process parameters (data source) by means of neural networks (or mathematical algorithms), i.e., by means of the virtual measuring device, virtual metrology results are made available to the process control system (e.g., R2R controller).

In a sixth application example, machine states are output by the virtual measuring device. For example, the virtual measuring device can predict wear on mechanical components based on physical measurement results MET. The R2R controller can thus either make an adjustment to the formula in order to achieve the same process results depending on the current wear, or it can trigger a repair/maintenance. Specifically, e.g., in case of epitaxy systems, the lamp run-time, in case of polishing systems, the pad life, or in case of precipitation systems, the target life can be determined with the aid of the virtual measuring device and thus made available to the process control in order to carry out automated R2R controller actions (e.g., various reset scenarios or formula corrections) based thereon.

In a seventh application example, a machine learning system for the virtual measuring device is used. The execution of data-intensive AI methods (decision-making procedures, classifications, cluster analysis, estimation and learning methods) often takes place not directly in the productive environment, but rather in derived offline environments. In order to make the results of such methods available to the production environment, the virtual measuring device can serve as a bridge between the AI algorithm and the process control system, or it can output the results as the virtual measurement results ART. Specifically, for example, distinguishable product-specific properties (e.g., speed ratings, product sub-groups) can be optimally summarized via cluster analysis and then suggested to the R2R controller as a context grouping.

1. A method for adjusting a process control in order to manufacture at least one component in production, comprising:
obtaining measurement results based on the at least one component in production;
determining, based on the measurement results, a parameterization of a specified process step for the at least one component in production or at least one subsequent component in production using a run-to-run (“R2R”) controller;
wherein the measurement results include either (i) virtual measurement results, or (ii) virtual measurement results and physical measurement results,
wherein the virtual measurement results are detected with a virtual measuring device,
wherein the virtual measuring device determines the virtual measurement results through software based on at least one data query, and
wherein the virtual measuring device is configured to output a plurality of measuring device states in a manner corresponding to an output of a physical measuring device.

2. The method according to claim 1, wherein the virtual measuring device carries out a measurement operation through software based on at least one data query and based on at least one data process step of a result of the at least one data query.

3. The method according to claim 1, wherein:
after carrying out the specified process step with the parameterization, at least one downstream measurement operation occurs on at least one component, the at least one component having been processed according to the specified process step,
the measurement results of the at least one downstream measurement operation are provided to the R2R controller as further measurement results, and
the measurement results of the at least one downstream measurement operation are virtual measurement results and/or physical measurement results.

4. An apparatus, comprising:
a processor configured to carry out the method according to claim 1.

5. The method according to claim 1, wherein a computer program comprises instructions which, when the computer program is executed by a computer, prompt the computer to carry out the method.

6. A non-transitory machine-readable storage medium on which the computer program according to claim 5 is stored.
